(19) United States
(12) Patent Application Publication
(10) Pub. No.: US 2025/0389769 A1
(43) Pub. Date: Dec. 25, 2025

(54) VOLTAGE LEVEL GENERATION ON A SINGLE OUTPUT LINE BASED ON DETECTED FAULT CONDITION

(71) Applicant: Intel Corporation, Santa Clara, CA (US)

(72) Inventors: Jagadish Singh, Bangalore (IN); Shilpa Mallikarjuna, Bangalore (IN); Sze Geat Pang, Gelugor (MY); Raghavendra Rao, Bangalore (IN); Joshua Resch, Portland, OR (US)

(21) Appl. No.: 19/307,329

(22) Filed: Aug. 22, 2025

(51) Int. Cl. G01R 31/28; G01R 35/00

(52) U.S. Cl. CPC G01R 31/2896; G01R 35/00

(57) ABSTRACT

A voltage regulator controller, including: detection circuitry configured to detect a plurality of distinct fault conditions associated with one or more power domains or system-level operating conditions, wherein the distinct fault conditions include different categories of faults or a same category of fault occurring in different power domains; and a current control circuit coupled to a single output line, the current control circuit configured to, for each detected fault condition, generate a corresponding current level that produces a corresponding voltage level on the output line, wherein each voltage level corresponds to a different fault condition.

### BACKGROUND

In upcoming platforms, Fast Voltage Mode (FVM) and zero load-line techniques are expected to become standard for increasing performance. At the same time, silicon circuits increasingly require excursion warnings earlier than traditional circuit-level protection to maintain system performance and reliability. The widening gap between the maximum required current draw and the effective current limit (allowable current draw) used during operation (based on the “FVM credit”) may lead to more frequent throttle events.

Throttle events could be triggered due to rail-specific concerns like thermal events on the specific voltage regulator (VR) rail, or overall system power being exceeded, or the battery voltage drooping below the minimum acceptable system voltage, or any other reason based on the operation of the VR controller and the different rails powering the System-on-Chip (SoC).

Traditional solutions that rely on dedicated event pins are becoming impractical. Each added pin increases cost and violates voltage regulator (VR) controller footprint constraints, which are critical for maintaining platform consistency. Silicon design teams continue to request a pin-efficient, low-latency means of early, per-rail fault signaling without adding protocol complexity or platform hardware overhead.

Historically, the voltage regulator's fault signal pin served as a unified, active-low alert for critical VR conditions, such as thermal or overcurrent faults, and optionally system-level violations. However, identifying the root cause required polling registers via a Serial Voltage Identification (SVID) interface, the power management bus, or the system management bus, adding latency and software burden. In high-availability systems like servers or discrete graphics cards, multiple dedicated pins were used, but at the cost of greater test complexity and pin count, while deviating from the established standard for the VR controller.

Adding more pins for FVM or system-level critical events strains SoC routing and disrupts footprint alignment. To avoid unnecessary throttling of the entire SoC and optimize performance through selective IP throttling or frequency demotion, it is important to identify which rail or domain triggered the event, allowing only the affected domain to be throttled.

### BRIEF DESCRIPTION OF THE FIGURES

FIG. 1 illustrates a block diagram of a system for encoding and communicating multiple distinct fault conditions from a controller to a system-on-chip (SoC) using a single output line, in accordance with aspects of the disclosure.

FIGS. 2A and 2B illustrate comparative graphs showing the difference between conventional binary voltage fault signaling and the disclosed multi-level analog encoding scheme for fault conditions.

FIG. 3 illustrates an example mapping table associating distinct fault sources with corresponding current sink values and resulting voltage levels on the voltage fault signal pin.

FIG. 4 illustrates a system-level implementation of the fault signaling architecture in which multiple agents can assert a fault signal onto a shared output line.

FIG. 5 illustrates a block diagram of a system in which the voltage levels used to encode fault conditions are generated by a programmable current sink circuit, in accordance with aspects of the disclosure.

### DETAILED DESCRIPTION

The present disclosure is directed to encoding and communicating multiple, distinct fault conditions from a voltage regulator controller to a system-on-chip (SoC) using a single output line. Unique analog voltage levels, generated by a current sink circuit, correspond to specific fault categories and may be monitored by the SoC to enable immediate, targeted responses. This approach supports source-specific fault signaling, reduces pin count, and maintains compatibility with legacy systems.

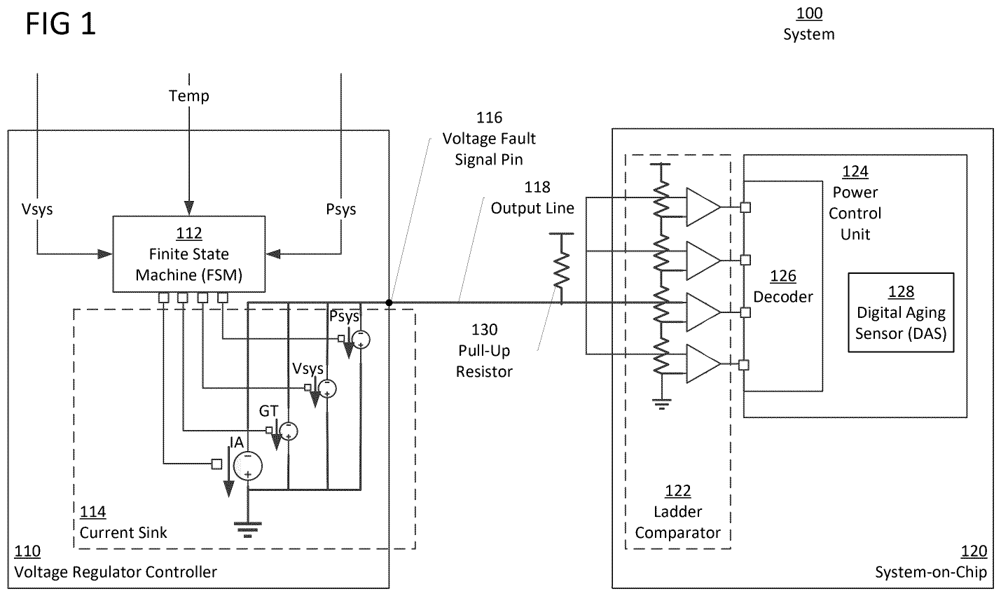

FIG. 1 illustrates a block diagram of a system 100 for encoding and communicating multiple distinct fault conditions from a controller to a system-on-chip (SoC) using a single output line, in accordance with aspects of the disclosure. The system 100 specifically utilizes a legacy voltage fault signal pin 116 connected to an output line 118 as the output line for transmitting fault information, thereby preserving backward compatibility and eliminating the need for additional pins. This legacy pin is repurposed to carry not just a binary fault, but multiple, source-specific fault codes using analog voltage levels.

The voltage regulator controller 110 comprises a finite state machine (FSM) 112 that receives inputs such as system voltage, system power, and temperature signals, and determines the presence and category of fault conditions. These include, but are not limited to, per-rail thermal violations, fast voltage mode (FVM) excursions, cycle-by-cycle current limiting events, system-level events such as a system power critical violation or system voltage minimum violation, and other power domain or system-level faults.

As used herein, the term “category of fault” (or “fault category”) refers to a grouping of fault conditions based on their underlying cause or mechanism. Categories of fault may include, for example, thermal violations, fast voltage mode excursions, current limiting events, system power critical violations, system voltage minimum violations, or other types of power or system-related faults. A category of fault may also refer to the same type of fault occurring in different power domains.

The FSM 112 controls a current sink circuit 114, which generates different current levels corresponding to the detected fault conditions. The current sink circuit 114 may be implemented using a digitally controlled current sink array, a segmented current sink, a resistor ladder, or a digital-to-analog converter (DAC). The current sink circuit 114 is coupled to the voltage fault signal pin 116, which is connected to the output line 118. The output line 118 is pulled up to a supply voltage by a pull-up resistor 130. For each detected fault condition, the FSM 112 configures the current sink circuit 114 to draw a specific current through the pull-up resistor 130, resulting in a unique voltage level on the output line 118. This voltage level encodes the specific fault condition according to the relationship:

$$V = {V}_{p u l l u p} - {I}_{s i n k} \times {R}_{p u l l u p}$$

The system 100 includes a SoC (System-on-Chip) 120, which may be configured to monitor the output line 118, determine the fault condition based on the voltage level on the output line 118, and initiate a targeted response based on the determined fault condition.

Design margins may be incorporated, with resistor and current values chosen to provide at least +20% margin for resistor tolerance, supply swing, noise, and SoC input thresholds. The voltage window width (e.g., 0.2 V per step) may be selected to ensure robust separation between event codes, even accounting for process and resistor tolerances, and to avoid overlap.

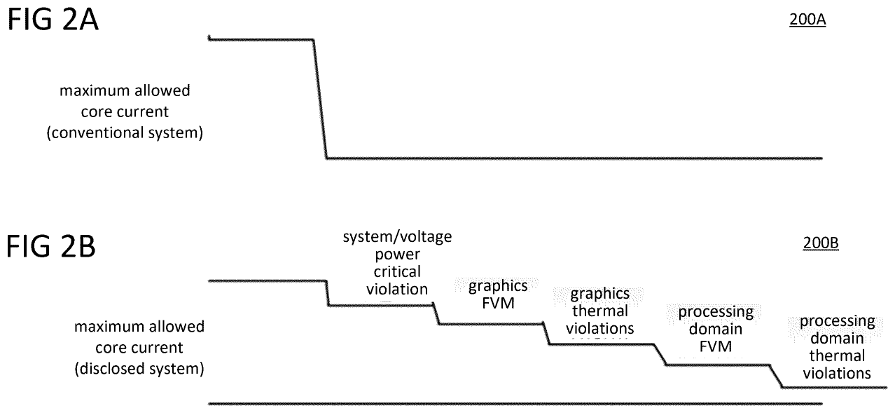

FIGS. 2A and 2B illustrate comparative graphs 200 (200A and 200B) showing the difference between conventional binary voltage fault signaling and the disclosed multi-level analog encoding scheme for fault conditions.

In each of the graphs 200A and 200B, the uppermost horizontal level is the minimum allowed current, which corresponds to the inactive or non-fault state of the voltage fault signal pin (for example, at 1.0V). This indicates normal operation, where the current drawn by the load is at or below the minimum allowable current, and no fault is asserted.

When a current-limit excursion occurs, the voltage on the voltage-fault signal pin 116 drops from the minimum current-based voltage limit line to a lower voltage level. In the conventional system, this is shown in the graph 200A as a sharp transition from the minimum current-based voltage limit line down to the fault voltage (e.g., 0V) line, which is the lowest horizontal line in the graph. This binary transition indicates a generic fault condition, without distinguishing the specific source or category of fault. In this mode, every current limit excursion results in the same assertion (if so programmed), and the SoC must subsequently poll the voltage regulator controller via the serial voltage identification (SVID) interface to determine the cause, introducing additional latency.

In the disclosed analog encoding scheme, the graph 200B includes several intermediate horizontal levels labeled according to specific fault conditions, such as system/voltage power critical violations, graphic rail FVM, graphics rail thermal violations, processing domain rail FVM, and processing domain rail thermal violations. Each of these lines corresponds to a unique voltage level on the voltage fault signal pin, which may be asserted when the corresponding fault condition occurs. These distinct voltage levels allow the SoC 120 to immediately identify the nature and source of the fault, without the need for SVID polling.

The graphs 200A and 200B thus demonstrate that, under the conventional system, all current limit excursions may be reported as identical binary events (minimum allowed core current to fault), resulting in delayed and non-specific (generic) SoC response. In contrast, the disclosed aspects enable immediate, source-specific reporting of current limit excursions and other faults (maximum allowed core current to a labeled intermediate line), allowing the SoC 120 to react promptly and efficiently, thereby improving system performance and responsiveness during graphics and compute-intensive workloads.

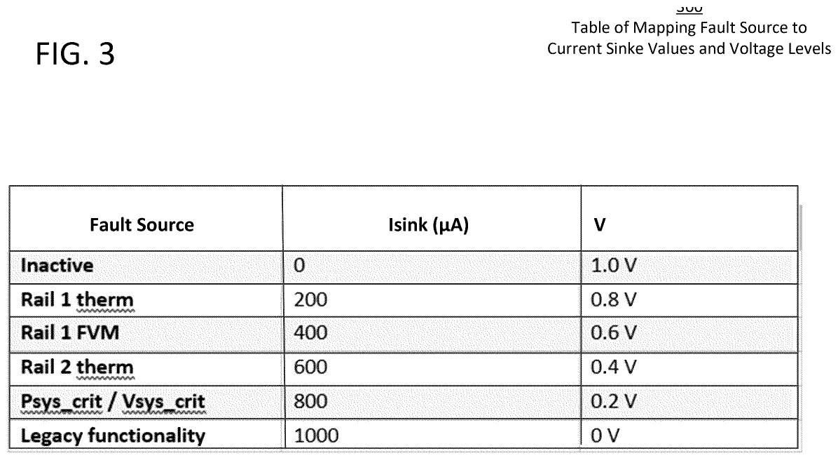

FIG. 3 illustrates an example mapping table 300 associating distinct fault sources with corresponding current sink values and resulting voltage levels on the voltage fault signal pin 116. The voltage level associated with a fault condition remains asserted for the duration of the fault, supporting both event detection and timing measurement.

Returning to FIG. 1, the output line 118 may be electrically coupled to SoC 120. Within SoC 120, a ladder comparator circuit 122 includes a set of comparators or an analog-to-digital converter (ADC) that monitors the voltage level on the output line 118. The SoC 120 may employ fast ADC or comparator sampling, and may use filtering, deglitching, or majority vote sampling to ensure noise-robust identification of the asserted voltage level. The measured voltage may be provided to a decoder 126, which compares the digitized voltage against a set of values to determine the specific fault condition being asserted. The decoder 126 may be further coupled to a power control unit 124, which initiates a targeted response based on the determined fault condition. The SoC 120 may respond by immediately throttling the affected domain (power domain or IP block, such as a CPU, GPU, or Uncore) or by operating a gradual reduction in operating frequency (a demotion algorithm), depending on the severity and persistence of the fault.

The FSM 112 supports strategies for handling multiple simultaneous faults. One strategy is strict prioritization, where the highest-priority fault is encoded. Another strategy may be combined encoding using additive current levels, if the SoC decoding capability allows for unique identification of fault combinations. The choice between these strategies is a design trade-off based on system requirements and SoC capability.

The system 100 supports dynamic assignment of voltage levels to fault conditions, allowing the mapping to be updated based on platform configuration, workload behavior, or fault handling priorities. Dynamic assignment and mapping updates may be triggered automatically at system boot, at predetermined intervals, or in response to system condition data, such as environmental changes or detected drift or workload change scenarios.

Calibration may be performed in a closed-loop process where the FSM 112 (calibration circuitry) of the voltage regulator controller 110 cycles through each fault encoding state, and the SoC 120 samples the resulting voltages to update detection thresholds. This compensates for process, voltage, temperature, and aging variations, maintaining clear separation between fault codes. Calibration may be triggered at boot, during scheduled maintenance, or on SoC request.

In some embodiments, calibration includes dynamic adjustment of current levels generated by the current sink circuit 114, e.g., via DAC or programmable resistor settings, to ensure robust voltage level separation. Feedback from the SoC 120 enables per-system calibration over time, accounting for drift or degradation.

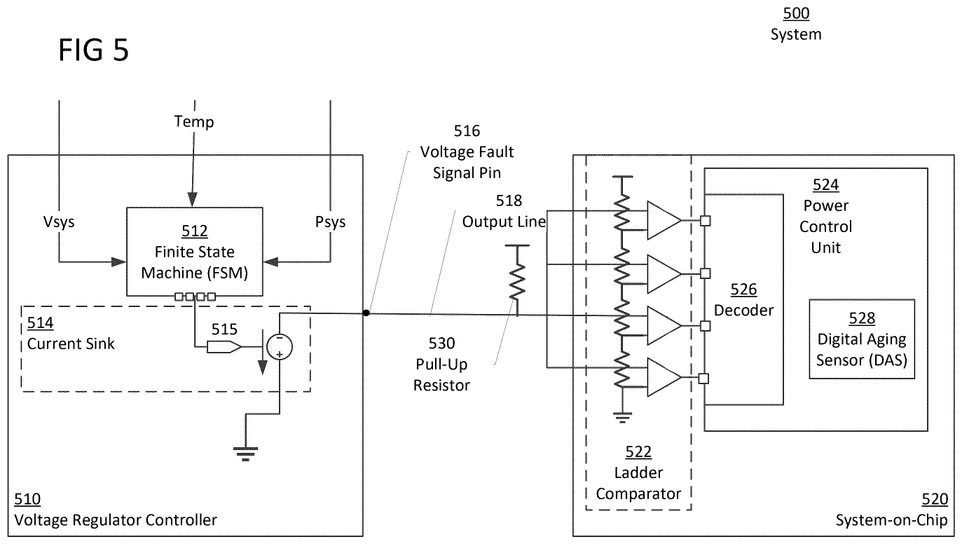

To further support long-term reliability, the system 100 may monitor system aging using either a Digital Aging Sensor (DAS) 128 (528 in FIG. 5), which measures stress and degradation of specific SoC paths, or usage-based monitoring, which compares Performance-core and Efficiency-core activity to reference usage models. Both methods enable estimation of per-core aging and remaining guard bands, guiding calibration and fault response strategies throughout the product lifecycle.

The system 100 also includes fail-safe and error handling features. If the voltage fault signal pin 116 is shorted or left floating (e.g., due to a missing pull-up), the system 100 asserts a reserved or error code, such as always asserted low (0V), which the SoC 120 can interpret as an untrusted or error state.

Empirical simulation results indicate that with a typical 1 kΩ pull-up resistor and 1.0 V supply, a ±1% resistor or process drift maintains voltage window separation greater than 0.08 V for a 0.2 V window width, demonstrating the robustness of the encoding scheme.

The architecture may be fully contained within existing pin assignments and controller/SoC footprints, requiring no additional pins or board routing, and may be scalable to support additional fault sources through firmware updates and calibration cycle extension. This design is highly manufacturable, aligns with platform cost and time-to-market objectives, and is future-proof as SoC scaling and the number of monitored rails increase. Backward compatibility may be maintained by allowing the output line 118 (voltage fault signal pin 116) to function as a binary fault signal in legacy systems that do not support multi-level voltage decoding. If analog decoding is not supported, the system defaults to open-drain digital mode, preserving legacy voltage fault signaling operation.

FIG. 1 thus depicts a system 100 that enables robust, low-latency, and pin-efficient communication of multiple, source-specific fault conditions from a voltage regulator controller 110 to an SoC 120 using a single, analog-encoded output line 118, with dynamic mapping, field calibration, and backward compatibility features.

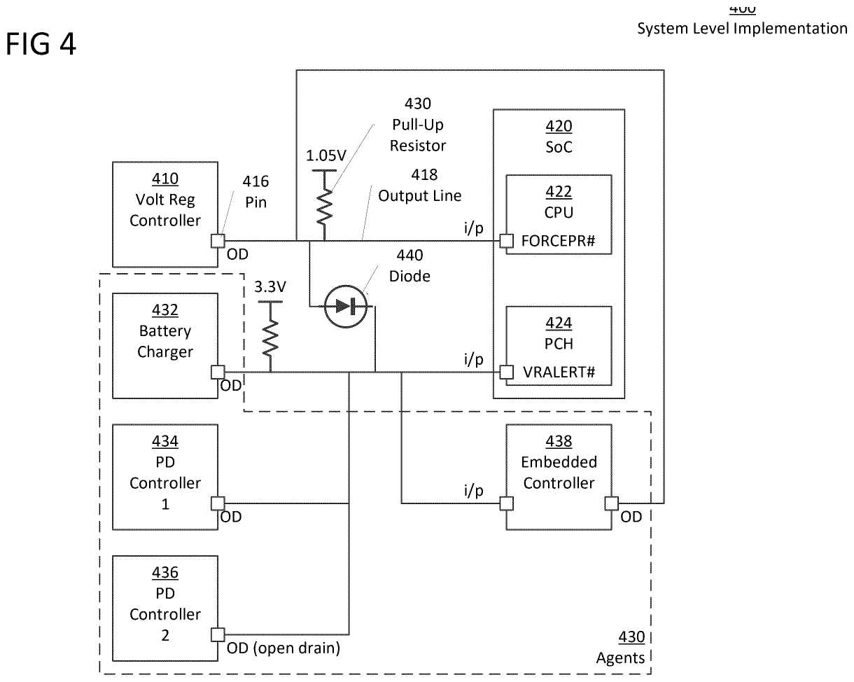

FIG. 4 illustrates a system-level implementation 400 of the fault signaling architecture in which multiple agents may be electrically connected to a shared output line 418, but each agent asserts signals in a distinct manner and for specific recipients. The agents include the voltage regulator controller 410, embedded controller (EC) 438, power delivery (PD) controllers 434 and 436, and battery charger 432.

The voltage regulator controller 410 may be configured to assert multi-level, analog-encoded fault signals on the output line 418, using an open-drain output at 1.05V or an equivalent low voltage, as is typical in designs for graphics cards, accelerators, and server chips. These multi-level signals may be intended specifically for the CPU 422, enabling the CPU to distinguish between different fault conditions and initiate targeted, per-domain corrective actions within the SoC 420.

The EC (Embedded Controller) 438, PD controllers 434 and 436, and battery charger 432 may be also connected to the output line 418, but they assert only binary (open-drain) signals. The EC 438 typically asserts a binary signal to the CPU 422 based on multiple system thermistors, and may also assert a fault in response to adapter disconnect events in systems with both AC and USB-C adapter support. In USB-C-only systems, this assertion may not be necessary as the PD controllers 434 and 436, as well as the battery charger 432, assert binary signals to indicate plug insert or detach events, which may be intended for the CPU 422, platform controller hub (PCH) 424, or EC 438, depending on system configuration.

A diode 440 may be electrically coupled between the voltage regulator controller 410 and the other fault signaling agents on the output line 418. This diode serves a dual isolation function, that is, it separates the multi-level analog voltage signals generated by the voltage regulator controller 410 from the binary fault signals asserted by the other agents, and it also isolates signal domains between specific recipients and board sections. This ensures that the voltage regulator controller 410 can provide any voltage output for the CPU 422 to sense, without interference from the binary agents, while the rest of the network continues to function as intended.

This arrangement allows the voltage regulator controller 410 to deliver source-specific, multi-level fault information to the CPU 422, while the EC 438, PD controllers 434 and 436, and battery charger 432 can continue to assert legacy binary signals to their intended recipients. The architecture supports a compatibility mode in which the output line 418 functions as a binary fault signal when the SoC 420 does not support multi-level voltage decoding, thereby preserving legacy operation.

Also, this implementation enables next-generation diagnostic, recovery, and reporting capabilities on battery and desktop platforms, bridging the gap between legacy simple-alert signals and the increasing need for precise, low-latency power integrity information, without increasing bill of materials, pin count, or firmware complexity. The network functionality remains fully intact, and the voltage regulator controller 410 can provide any voltage output for the CPU 422 to sense, while the rest of the agents and the system continue to operate as intended.

FIG. 5 illustrates a block diagram of an apparatus 500 in which the voltage levels used to encode fault conditions may be generated by a programmable current sink circuit 514. The programmable current sink circuit 514 may be configured to draw different current levels through a pull-up resistor 530 coupled to the output line 518, with each current level corresponding to a different fault condition. In one aspect, the current sink circuit 514 comprises a digital-to-analog converter (DAC) 515, which may be programmable and capable of generating distinct current levels for each fault condition based on a mapping table, such as shown in FIG. 3. The voltage regulator controller 510 may implement the programmable DAC 515 to provide a different value for the current source depending on the detected fault, enabling flexible and precise analog encoding of multiple fault sources.

The architecture of FIG. 5 supports the assignment of new codes for additional fault sources or events, such as voltage overshoot, new power rails, or refined FVM warning thresholds, without requiring architectural rework. These changes may be set on a per-platform basis or dynamically updated based on the specific blocks on the SoC 520 that are being exercised during a given workload and are deemed worthy of tracking to enhance performance. The architecture of FIG. 1 can also support the described feature in a limited way due to the limited number of discrete levels it can convey.

Notably, no dedicated pin is required from the voltage regulator controller 510 to convey yet another fault condition when the voltage regulator enters a current limit mode during voltage slew. This condition may be currently conveyed through the same output line 518 as a generic fault, and the SoC 520 may be expected to determine the cause through SVID reads if necessary. With the described method, this fault can be encoded into a suitable voltage level for the SoC to act on. This design provides a scalable and flexible solution for encoding and communicating a wide range of fault conditions using a single output line.

By enabling SoCs to discriminate among the root causes of voltage fault signal assertions and to apply corrective action only to the responsible domain, such as CPU, GPU, or Uncore, the aspects of this disclosure reduce overall performance loss, which becomes more important as the frequency of power management events rises due to the growing Fast Voltage Mode (FVM) credit and aggressive workload scaling.

The solution described herein may be fully compatible with standard voltage regulator controller footprints and multiple platforms where footprint compatibility between SoCs may be expected, simplifying design and integration for original equipment manufacturers (OEMs), original design manufacturers (ODMs), and silicon partners and ensuring no increase in pinout, routing, or physical area.

Direct performance uplift may be realized for graphics and compute workloads, particularly under conditions where dedicated pins for events like system power critical violations or current limit excursions were implemented. Under graphics workloads, the current limit excursions that occur very often during systolic workloads may be conveyed to the SoC over the serial voltage identification interface, which adds latency. The implementation disclosed here provides a far more elegant solution with the least latency for the SoC to react to the excursion.

The techniques described in this disclosure may also be illustrated in the following examples.

Example 1. A voltage regulator controller, comprising: detection circuitry configured to detect a plurality of distinct fault conditions associated with one or more power domains or system-level operating conditions, wherein the distinct fault conditions include different categories of faults or a same category of fault occurring in different power domains; and a current control circuit coupled to a single output line, the current control circuit configured to, for each detected fault condition, generate a corresponding current level that produces a corresponding voltage level on the output line, wherein each voltage level corresponds to a different fault condition.

Example 2. The voltage regulator controller of example 1, wherein the current control circuit comprises a programmable current sink circuit configured to draw different current levels through a pull-up resistor coupled to the output line, each current level corresponding to a different fault condition.

Example 3. The voltage regulator controller of any one or more of examples 1-2, wherein the programmable current sink circuit comprises a digital-to-analog converter (DAC) configured to generate distinct current levels corresponding to different fault conditions.

Example 4. The voltage regulator controller of example 2, wherein the programmable current sink circuit comprises multiple current sink branches, each branch being selectively activated based on a corresponding fault condition to produce a distinct total current on the output line.

Example 5. The voltage regulator controller of any one or more of examples 1-4, further comprising calibration circuitry configured to adjust the current levels generated by the current control circuit based on changes in system characteristics over time.

Example 6. The voltage regulator controller of any one or more of examples 1-5, further comprising circuitry configured to operate in a compatibility mode in which the output line functions as a binary fault signal.

Example 7. The voltage regulator controller of any one or more of examples 1-6, wherein, when multiple fault conditions occur simultaneously, the detection circuitry is configured to select a fault condition based on a predetermined priority hierarchy and assert a voltage level corresponding to the selected fault condition or assert a voltage level representing a combined encoding using additive current levels.

Example 8. A system, comprising: a voltage regulator controller according to any one or more of examples 1-7; and a system-on-chip configured to: monitor the output line; determine the fault condition based on the voltage level on the output line; and initiate a targeted response based on the determined fault condition.

Example 9. The system of example 8, wherein the response initiated by the system-on-chip comprises a corrective action targeted to the one or more specific power domains or system-level operating conditions within the system-on-chip based on the determined fault condition.

Example 10. The system of any one or more of examples 8-9, wherein the system-on-chip is further configured to dynamically assign voltage levels to fault conditions such that mapping between voltage levels and fault conditions is updated based on platform configuration, workload behavior, or fault handling priorities, wherein the dynamic assignment is performed during system boot, at predetermined intervals, or in response to system condition data.

Example 11. The system of any one or more of examples 8-10, wherein the system-on-chip is configured to perform a calibration operation to adjust one or more thresholds used to determine the fault condition based on the voltage level present on the output line.

Example 12. The system of example 11, wherein the calibration operation is based at least in part on data indicative of changes in system characteristics over time.

Example 13. The system of any one or more of examples 8-12, wherein the system-on-chip is configured to perform a calibration operation in a closed-loop manner by commanding the voltage regulator controller to cycle through each fault encoding state, sampling resulting voltage levels on the output line, and updating detection thresholds based on the sampled values.

Example 14. The system of example 11, wherein the calibration operation is initiated automatically at system startup, during a scheduled calibration interval, or in response to a request from the system-on-chip.

Example 15. The system of any one or more of examples 8-14, wherein the system-on-chip is configured to sample the voltage level on the output line using an analog-to-digital converter (ADC) in response to a change in the voltage level, and to determine the corresponding fault condition based on the sampled value.

Example 16. The system of any one or more of examples 8-15, wherein the distinct fault conditions comprise a thermal violation, a fast voltage mode excursion, or a current limiting event in the one or more power domains, a system power critical violation, or a system voltage minimum violation.

Example 17. The system of any one or more of examples 8-16, wherein the system-on-chip is configured to store a mapping table associating each voltage level on the output line with a corresponding fault condition, and to update the mapping table during calibration or in response to changes in platform configuration or workload behavior.

Example 18. The system of any one or more of examples 8-17, wherein the voltage level associated with a fault condition remains asserted for a duration corresponding to persistence of the fault condition.

Example 19. The system of any one or more of examples 8-18, further comprising a digital aging sensor configured to measure stress and degradation of the system-on-chip, wherein the system-on-chip is further configured to adjust calibration parameters for fault detection based at least in part on measurements from the digital aging sensor.

Example 20. The system of any one or more of examples 8-19, wherein the system-on-chip is further configured to adjust one or more calibration parameters used for fault detection based at least in part on usage-based monitoring of the system-on-chip.

Example 21. A voltage regulator controller, comprising: detection means for detecting a plurality of distinct fault conditions associated with one or more power domains or system-level operating conditions, wherein the distinct fault conditions include different categories of faults or a same category of fault occurring in different power domains; and a current control means coupled to a single output line, the current control for, for each detected fault condition, generating a corresponding current level that produces a corresponding voltage level on the output line, wherein each voltage level corresponds to a different fault condition.

Example 22. The voltage regulator controller of example 21, wherein the current control means comprises a programmable current sink circuit configured to draw different current levels through a pull-up resistor coupled to the output line, each current level corresponding to a different fault condition.

Example 23. The voltage regulator controller of any one or more of examples 21-22, wherein the programmable current sink circuit comprises a digital-to-analog converter (DAC) configured to generate distinct current levels corresponding to different fault conditions.

Example 24. The voltage regulator controller of example 22, wherein the programmable current sink circuit comprises multiple current sink branches, each branch being selectively activated based on a corresponding fault condition to produce a distinct total current on the output line.

Example 25. The voltage regulator controller of any one or more of examples 21-24, further comprising calibration means for adjusting the current levels generated by the current control circuit based on changes in system characteristics over time.

Example 26. The voltage regulator controller of any one or more of examples 21-25, further comprising circuit means for operating in a compatibility mode in which the output line functions as a binary fault signal.

Example 27. The voltage regulator controller of any one or more of examples 21-26, wherein, when multiple fault conditions occur simultaneously, the detection means is for selecting a fault condition based on a predetermined priority hierarchy and assert a voltage level corresponding to the selected fault condition or assert a voltage level representing a combined encoding using additive current levels.

Example 28. A system, comprising: a voltage regulator controller according to any one or more of examples 21-27; and a system-on-chip configured to: monitor the output line; determine the fault condition based on the voltage level on the output line; and initiate a targeted response based on the determined fault condition.

Example 29. The system of example 28, wherein the response initiated by the system-on-chip comprises a corrective action targeted to the one or more specific power domains or system-level operating conditions within the system-on-chip based on the determined fault condition.

Example 30. The system of any one or more of examples 28-29, wherein the system-on-chip is further configured to dynamically assign voltage levels to fault conditions such that mapping between voltage levels and fault conditions is updated based on platform configuration, workload behavior, or fault handling priorities, wherein the dynamic assignment is performed during system boot, at predetermined intervals, or in response to system condition data.

Example 31. The system of any one or more of examples 28-30, wherein the system-on-chip is configured to perform a calibration operation to adjust one or more thresholds used to determine the fault condition based on the voltage level present on the output line.

Example 32. The system of example 31, wherein the calibration operation is based at least in part on data indicative of changes in system characteristics over time.

Example 33. The system of any one or more of examples 28-32, wherein the system-on-chip is configured to perform a calibration operation in a closed-loop manner by commanding the voltage regulator controller to cycle through each fault encoding state, sampling resulting voltage levels on the output line, and updating detection thresholds based on the sampled values.

Example 34. The system of example 31, wherein the calibration operation is initiated automatically at system startup, during a scheduled calibration interval, or in response to a request from the system-on-chip.

Example 35. The system of any one or more of examples 28-34, wherein the system-on-chip is configured to sample the voltage level on the output line using an analog-to-digital converter (ADC) in response to a change in the voltage level, and to determine the corresponding fault condition based on the sampled value.

Example 36. The system of any one or more of examples 28-35, wherein the distinct fault conditions comprise a thermal violation, a fast voltage mode excursion, or a current limiting event in the one or more power domains, a system power critical violation, or a system voltage minimum violation.

Example 37. The system of any one or more of examples 28-36, wherein the system-on-chip is configured to store a mapping table associating each voltage level on the output line with a corresponding fault condition, and to update the mapping table during calibration or in response to changes in platform configuration or workload behavior.

Example 38. The system of any one or more of examples 28-37, wherein the voltage level associated with a fault condition remains asserted for a duration corresponding to persistence of the fault condition.

Example 39. The system of any one or more of examples 28-38, further comprising a digital aging sensor means for measuring stress and degradation of the system-on-chip, wherein the system-on-chip is further configured to adjust calibration parameters for fault detection based at least in part on measurements from the digital aging sensor.

Example 40. The system of any one or more of examples 28-39, wherein the system-on-chip is further configured to adjust one or more calibration parameters used for fault detection based at least in part on usage-based monitoring of the system-on-chip.

Although specific aspects have been illustrated and described herein, it will be appreciated by those of ordinary skill in the art that a variety of alternate and/or equivalent implementations may be substituted for the specific aspects shown and described without departing from the scope of the present application. This application is intended to cover any adaptations or variations of the specific aspects discussed herein.

1. A voltage regulator controller, comprising:
detection circuitry configured to detect a plurality of distinct fault conditions associated with one or more power domains or system-level operating conditions, wherein the distinct fault conditions include different categories of faults or a same category of fault occurring in different power domains; and
a current control circuit coupled to a single output line, the current control circuit configured to, for each detected fault condition, generate a corresponding current level that produces a corresponding voltage level on the output line, wherein each voltage level corresponds to a different fault condition.

2. The voltage regulator controller of claim 1, wherein the current control circuit comprises a programmable current sink circuit configured to draw different current levels through a pull-up resistor coupled to the output line, each current level corresponding to a different fault condition.

3. The voltage regulator controller of claim 2, wherein the programmable current sink circuit comprises a digital-to-analog converter (DAC) configured to generate distinct current levels corresponding to different fault conditions.

4. The voltage regulator controller of claim 2, wherein the programmable current sink circuit comprises multiple current sink branches, each branch being selectively activated based on a corresponding fault condition to produce a distinct total current on the output line.

5. The voltage regulator controller of claim 1, further comprising calibration circuitry configured to adjust the current levels generated by the current control circuit based on changes in system characteristics over time.

6. The voltage regulator controller of claim 1, further comprising circuitry configured to operate in a compatibility mode in which the output line functions as a binary fault signal.

7. The voltage regulator controller of claim 1, wherein, when multiple fault conditions occur simultaneously, the detection circuitry is configured to select a fault condition based on a predetermined priority hierarchy and assert a voltage level corresponding to the selected fault condition or assert a voltage level representing a combined encoding using additive current levels.

8. A system, comprising:
a voltage regulator controller according to claim 1; and
a system-on-chip configured to:
monitor the output line;
determine the fault condition based on the voltage level on the output line; and
initiate a targeted response based on the determined fault condition.

9. The system of claim 8, wherein the response initiated by the system-on-chip comprises a corrective action targeted to the one or more specific power domains or system-level operating conditions within the system-on-chip based on the determined fault condition.

10. The system of claim 8, wherein the system-on-chip is further configured to dynamically assign voltage levels to fault conditions such that mapping between voltage levels and fault conditions is updated based on platform configuration, workload behavior, or fault handling priorities, wherein the dynamic assignment is performed during system boot, at predetermined intervals, or in response to system condition data.

11. The system of claim 8, wherein the system-on-chip is configured to perform a calibration operation to adjust one or more thresholds used to determine the fault condition based on the voltage level present on the output line.

12. The system of claim 11, wherein the calibration operation is based at least in part on data indicative of changes in system characteristics over time.

13. The system of claim 8, wherein the system-on-chip is configured to perform a calibration operation in a closed-loop manner by commanding the voltage regulator controller to cycle through each fault encoding state, sampling resulting voltage levels on the output line, and updating detection thresholds based on the sampled values.

14. The system of claim 11, wherein the calibration operation is initiated automatically at system startup, during a scheduled calibration interval, or in response to a request from the system-on-chip.

15. The system of claim 8, wherein the system-on-chip is configured to sample the voltage level on the output line using an analog-to-digital converter (ADC) in response to a change in the voltage level, and to determine the corresponding fault condition based on the sampled value.

16. The system of claim 8, wherein the distinct fault conditions comprise a thermal violation, a fast voltage mode excursion, or a current limiting event in the one or more power domains, a system power critical violation, or a system voltage minimum violation.

17. The system of claim 8, wherein the system-on-chip is configured to store a mapping table associating each voltage level on the output line with a corresponding fault condition, and to update the mapping table during calibration or in response to changes in platform configuration or workload behavior.

18. The system of claim 8, wherein the voltage level associated with a fault condition remains asserted for a duration corresponding to persistence of the fault condition.

19. The system of claim 8, further comprising a digital aging sensor configured to measure stress and degradation of the system-on-chip, wherein the system-on-chip is further configured to adjust calibration parameters for fault detection based at least in part on measurements from the digital aging sensor.

20. The system of claim 8, wherein the system-on-chip is further configured to adjust one or more calibration parameters used for fault detection based at least in part on usage-based monitoring of the system-on-chip.
